(19) United States
(12) Patent Application Publication
(10) Pub. No.: US 2002/0125507 A1
(43) Pub. Date: Sep. 12, 2002

(54) Interruptable high-voltage current limiter suitable for monolithic integration

(76) Inventors: James Ray Washburn, Scottsdale, AZ (US); George Michael Templeton, Tempe, AZ (US)

Correspondence Address: James R. Washburn, 3337 N. 62nd St., Scottsdale, AZ, 85251, US

(21) Appl. No.: 10/090,535

(22) Filed: Mar. 5, 2002

Related U.S. Application Data
(60) Provisional application No. 60/273,725, filed on Mar. 7, 2001.

(51) Int. Cl. H01L 29/76

(52) U.S. Cl. 257/213

(57) ABSTRACT

Interruptible high-voltage current limiter in a monolithic configuration: The structure comprises serially-connected complementary depletion-mode FET's where at least the gate of one of the FET's shares a common semiconductor region with the drain of the other FET. In a preferred embodiment, the FET's comprise a vertical n-channel depletion mode FET and a lateral depletion mode P-type FET. A Zener diode may be used to help control the cutoff voltage of the limiter.

### BACKGROUND OF THE INVENTION

This invention relates to semiconductor current limiters having decreasing current with increasing applied voltage and, more particularly, to a semiconductor current limiter having high-voltage capability in a monolithic embodiment.

In many electronic protection applications, simple over-voltage limitation using a varistor or break-over thyristor is inadequate. An example is the protection of semiconductor equipment connected to the metallic lines in telecommunication and multimedia equipment, where over-voltage devices shunt the lines in order to protect against transients such as lightning and power line cross. In a telephone system, for example, the protection voltage at a station location must be high enough not to clip the ring signal voltage which is well above the normal off-hook operating voltages. In some cases thermistors which open on over-current are used in series with the lines to augment over-voltage protection. These thermistor devices are essentially self-healing fuses which being thermally activated are not particularly efficacious against fast transients and may not reset to an on state suitable for continued use in the system.

Ideally a fast-acting self-resetting electronic fuse could be used in series with the equipment to be protected. Such a fuse or switch would require low insertion loss, fast diminution of current with increase in voltage, blocking capability above the maximum system operating voltage, and automatic resetting preferably just above the minimum system operating voltage. For a typical telecommunications system, these requirements mean insertion loss on the order of 5 ohms, sub-microsecond turnoff times, breakdown voltage on the order of 400 volts, and a reset voltage in excess of the 50 volt operating battery. To achieve volume deployment such a device would also have to be substantially linear in the on-voltage range of 0 to 1 volt and be very low cost, preferably in a two-terminal configuration.

U.S. Pat. No. 3,916,220 to Rovetti demonstrates that it is known to use serially-connected complementary junction field-effect transistors (JFET's) to provide a two-terminal current response which at first increases linearly with voltage and then decreases sharply as the voltage is increased. Brown U.S. Pat. No. 4,533,970 expands on this theme with a slightly different bias circuit and the observation that depletion-mode metal-oxide-semiconductor field-effect transistors (MOSFET's) might alternatively be used. Harris U.S. Pat. No. 5,742,463 observes that high-voltage discrete JFET's are hard to come by commercially so that these types of circuits are limited to low-voltage applications. Harris goes on to teach circuit configurations comprising three or more serial FET's in order to raise the blocking voltage capability.

Despite numerous patents citing the above references, there appears to be no widespread deployment of interruptible current limiters in telecommunications systems. Indeed if such a device were available at low cost it could also be used to provide two current pulses during a single half cycle in order to reduce filtering costs in power supplies. Low-cost interruptible current limiter availability is largely due to the fact that that circuits shown in the cited prior art are difficult to implement in monolithic format where high-voltage capability is required. Thus a need has existed for an improved interruptible high-voltage current limiter in a monolithic format.

### BRIEF SUMMARY OF THE INVENTION

It is an object of this invention to provide a current limiter with high-voltage blocking capability and reset at a controllable lower voltage.

It is a further object of this invention to provide a current limiter comprising complementary serial FET's in monolithic form.

It is yet another object of this invention to provide a low-cost two-terminal current limiter with high-voltage capability.

It is yet a further object of this invention to provide current-limiting protector for metallic communication lines in monolithic format.

It is still a further object of this invention to provide a low-cost resettable current limiter by minimizing the required parts count.

In accordance with one embodiment of this invention, serial complementary FET's comprise a two-terminal current-limiting device wherein one of the terminals is connected with the gate of one of the FET's through Zener diode means for controlling the cutoff and reset voltages of the limiter.

In accordance with another embodiment of the current limiter according to the present invention, a semiconductor substrate of one conductivity type comprises the drain of one of two serially-connected complementary FET's and at least a portion of the gate region of the other of the FET's.

In accordance with yet another embodiment of this invention, serially-connected complementary FET's occupy the same semiconductor substrate as a Zener diode and resistive divider means for controlling the channel conduction in one of the FET's.

In accordance with still another embodiment of this invention, there is provided a high-voltage current-limiting structure with a controlled reset voltage in a monolithic embodiment which requires no other components than two depletion-mode FET's.

These and other objects, features, and characteristics of the invention will be more particularly described in the following more detailed description of the preferred embodiments.

### BRIEF DESCRIPTION OF THE SEVERAL VIEWS OF THE DRAWING

FIG. 1 is a schematic embodiment of a current limiter for the purpose of describing the essential features of the prior art.

FIG. 2 is a schematic rendering of a bias configuration for a current limiter according to the present invention.

FIG. 3 shows a schematic of another bias configuration suitable for the current limiter of the current invention.

FIG. 4 is a perspective view of a monolithic semiconductor substrate comprising the current limiter of the instant invention.

FIG. 5 is a perspective view of a semiconductor substrate arrangement suitable for monolithic integration of a high-voltage current limiter having minimal parts count according to a preferred embodiment of the present invention

### DETAILED DESCRIPTION OF THE INVENTION

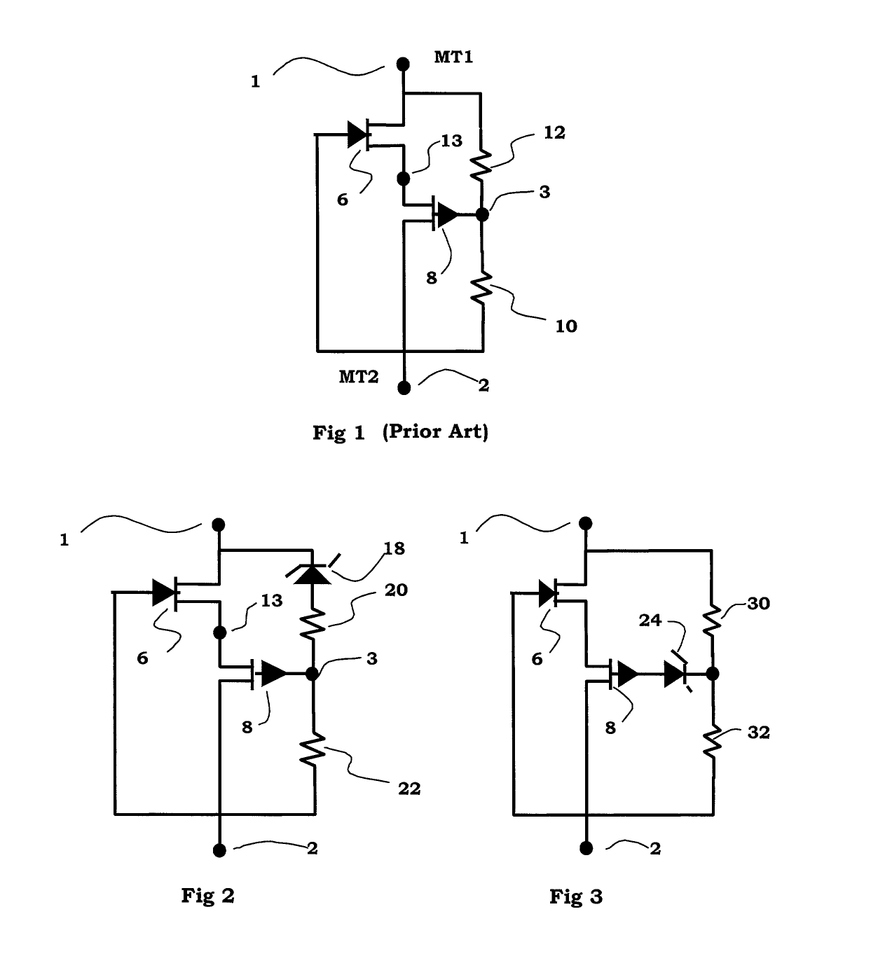

Referring now to FIG. 1, there is shown prototypical protection circuit of the prior art. First main terminal 1 is connected to the drain terminal of depletion-mode field effect transistor 6. The source terminal of transistor 6 is connected at internal node 13 to the source of a second depletion-mode field effect transistor 8 having a channel conductivity type opposite to that of transistor 6. The drain of the complementary transistor 8 is connected with the second main terminal 2 of the circuit, as is the gate of transistor 6. The gate of transistor 8 is coupled to a divider network comprising resistors 10 and 12 which are connected across the first and second main terminals. The circuit of FIG. 1 is connected in series with a load (not shown) to be protected.

In operation, as the voltage at terminal 1 is increased with respect to that at terminal 2 (zero reference) the current increases through both of the transistors as does the voltage at node 13. As this potential continues to rise the n-channel transistor 6 begins to turn off, reducing the current through the main terminal provided the conductance of the divider is small compared with that of the transistors. When the potential at node 13 is equal to the pinch-off voltage VTN of the n-channel transistor 6, current substantially ceases through that transistor as well as through the p-channel transistor 8. The potential at the gate of the p-type transistor must then be equal to sum of the magnitude of its pinch-off voltage VTP plus VTN. The current through the transistors substantially stops for main terminal voltages above a cutoff voltage equal to the divider ratio R times the sum of the pinch-off voltages, so that the current through the protected load is limited by the conductance of the divider network. The voltage must be reduced below the cutoff voltage in order to reset the limiter. As an example, the cutoff voltage must be above the approximately 50 volt battery voltage in a typical telephone system.

To achieve a high cutoff voltage either at least one of the pinch-off voltages must be high or the divider ratio R must be large. If R is large, there is a tolerancing issue with the cutoff voltage. If R is small substantially all the applied voltage appears across the gate of transistor 8 so that it must have high breakdown voltage capability, increasing its cost and the difficulty of monolithic integration.

Possible circuit solutions to this difficulty according to the present invention are shown in FIGS. 2 and 3. The circuit of FIG. 2 is that of FIG. 1 with the addition of Zener diode 18 which reduces the potential at the gate of transistor 8 (node 3) and increases the cutoff voltage of the limiter circuit by the amount of the Zener voltage, giving an additional degree of control. FIG. 3 shows another way to incorporate a Zener diode 24 into the circuit of FIG. 1 to similarly decrease the voltage on the gate of transistor 8.

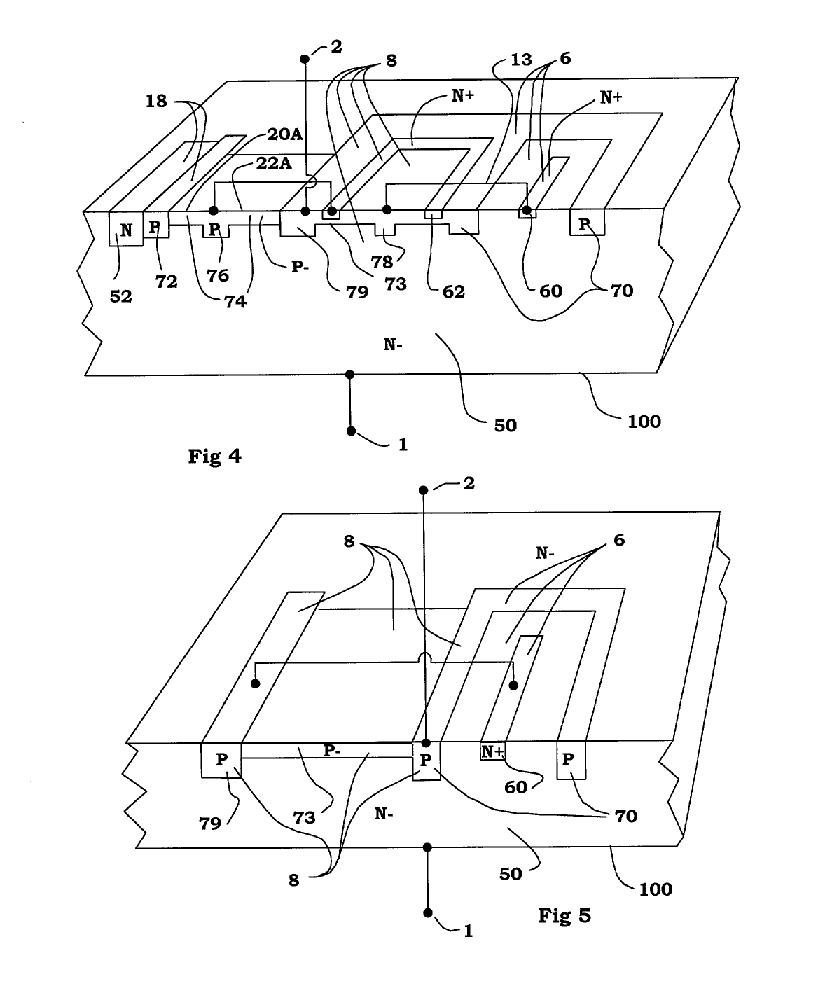

Referring now to FIG. 4, a semiconductor substrate portion 100 including the elements essential to the monolithic integration of the improved limiter circuit according to FIG. 2 is shown in perspective view. N-region 50 is chosen to have sufficient resistivity to support the breakdown voltage of the current limiter, and connects with a first main terminal 1 of the current limiter device. Vertical depletion mode n-type transistor 6 comprises the lightly doped drain region 50, the heavily doped N+ source region 60, and the gate region 70. The source of transistor 6 is connected (13) with the source 78 of p-type depletion mode transistor 8 whose drain connects with second main terminal 2 of the limiter structure. Heavily-doped N+ region 62 comprises a gate of the p-channel transistor 6 and the gate region 62 completely surrounds the source 78. Zener diode 18 comprises an N type region 52 and P type region 72. Lightly doped P regions 20A and 22A form the gate voltage divider resistors; they are tapped at P region 76 which is connected with the gate 62 of p-channel transistor 8.

It will be noted that p-channel transistor 8 comprises two gate regions: the heavily doped N+ region 62 at the top surface of the substrate and lightly doped N region 50 of the substrate 100. In order to have the high conductance necessary for a low-resistance limiter the channel region 73 of the transistor 8 must be relatively heavily doped and accordingly will exhibit a relatively low breakdown with gate region 62. Thus gate 62 must not be connected with effective gate region 50 which sees the maximum potential applied to the circuit. Note especially that the transistor 8 has only the maximum potential VTN applied across its channel and hence need not be a high-voltage vertical device like transistor 6. The potential at the gate of transistor 8 is limited by the combination of the Zener diode 18 and the divider network. It is this combination of features that enables cost-effective monolithic integration of the current limiter circuit.

FIG. 5 shows another embodiment of the current limiter according to the present invention. Here the numbered semiconductor regions generally correspond to those in FIG. 4 except that all of the regions corresponding to the Zener diode and the divider network are absent, as is the top gate region 62 of the transistor 8. Substrate N region 50 is now common to the drain of the n-channel transistor 6 and the only gate of the p-channel transistor 8. Recall that the telephone application indicated a cutoff voltage above 50 volts. In the structure of FIG. 5, since there is no top gate with its attendant low breakdown voltage, the pinch off voltage of the p-channel transistor may be raised even though the channel region 73 is relatively highly doped because depletion into the lightly doped substrate region will raise the pinch off voltage as compared with the heavily doped gate region 62 in FIG. 4. From a design point of view, the resistivity of the region 50 is selected to meet the minimum breakdown voltage requirement and the channel doping is chosen for complete depletion at the desired pinch off voltage.

In addition to obviating the extra chip area and process complexity associated with the Zener diode and the resistor, the approach of FIG. 5 has the additional advantage that there are no shunt elements to draw current when the limiter is shut off at high voltage. This monolithic embodiment is an interesting example of a situation where reducing the component count improves the performance.

Referring again to FIGS. 4 and 5, there are shown serially-connected complementary depletion-mode field effect transistors where the drain of the n-channel transistor 6 comprises a lightly-doped substrate region 50 in common with a bottom gate region of the p-channel transistor 8, which in turn has its drain region 79 in FIG. 4 or 70 in FIG. 5 in common with the gate region 70 of the n-channel transistor 6. Thus each of the complementary transistors has a gate region common to a drain region of the other.

It will be noted that the n-channel transistor is a vertical FET, whereas the p-channel transistor is a horizontal FET. Since the channel of the p-type transistor need only support the pinch-off voltage of the n-channel transistor, the p-type channel can be quite short, so that the lateral arrangement saves considerable space. The gate to drain voltage across the bottom gate of the p-channel transistor is supported by the same substrate regions.

While the present invention has been particularly described with respect to preferred embodiments thereof, it will be obvious to those skilled in the art that departures in details may be made without departing from the spirit and scope of the invention. For example, the conductivity types of the vertical and lateral transistors may be exchanged, or the vertical transistor could be of the MOS type. Additional transistors could be added on the same substrate so that the current limiter exhibits bilateral operation.

What we claim is:

1. A high-voltage monolithic current-limiter device comprising, in combination:
a semiconductor substrate region of a first conductivity type, a first depletion-mode FET of a first conductivity-type formed in said substrate region and having a source region, a drain region, and a gate region, a second depletion-mode FET of a second conductivity-type opposite said first conductivity type formed in said substrate region, said second FET having a source region, a drain region, and a gate region, where said semiconductor substrate region of said first conductivity type comprises the said drain of said first FET and the said gate of said second FET.

2. The current-limiter device according to claim 1, where said first FET comprises a vertical transistor and said second FET comprises a lateral transistor.

3. The current-limiter device according to claim 1 wherein said second FET includes a second gate comprising a region of said first conductivity-type separate and distinct from said semiconductor substrate region of said first conductivity-type.

4. The current-limiter device according to claim 3, further including voltage-divider means connected with said drain of said first FET, said drain of said second FET, and said second gate of said second FET for limiting the voltage applied to said second gate of said second FET.

5. The current-limiter device according to claim 4, where said voltage divider means comprises two resistors and a Zener diode formed in said substrate region.

6. The current-limiter device according to claim 1, where said first conductivity-type is n conductivity-type.

7. The current-limiter device according to claim 3, where said first FET comprises a vertical transistor and said second FET comprises a lateral transistor.

8. The current-limiter device according to claim 1 where said second FET breaks down at voltage less than the second FET.

9. The current-limiter device according to claim 4, where said voltage-divider means limits the voltage on said second gate of said second FET to less than its breakdown voltage.

10. The current limiter device according to claim 1, further including a first semiconductor region, said first semiconductor region of said second conductivity-type comprising both a gate of said first depletion-mode FET and a drain of said second depletion-mode FET.
